(19) United States
(12) Patent Application Publication
(10) Pub. No.: US 2025/0351701 A1
(43) Pub. Date: Nov. 13, 2025

(54) DISPLAY DEVICE, METHOD OF MANUFACTURING DISPLAY DEVICE, AND ELECTRONIC DEVICE COMPRISING DISPLAY DEVICE

(71) Applicant: Samsung Display Co., LTD., Yongin-si (KR)

(72) Inventor: Joo Nyung JANG, Yongin-si (KR)

(73) Assignee: Samsung Display Co., LTD., Yongin-si (KR)

(21) Appl. No.: 19/039,537

(22) Filed: Jan. 28, 2025

(30) Foreign Application Priority Data
May 9, 2024 (KR) 10-2024-0060943

(51) Int. Cl. H10K 59/38; H10K 59/12; H10K 59/122

(52) U.S. Cl. CPC H10K 59/38; H10K 59/1201; H10K 59/122

(57) ABSTRACT

Provided are a display device, a method of manufacturing the display device, and an electronic device comprising the display device. The display device includes a display layer including a light emitting element on a base layer, a light controlling member disposed on the display layer, the light controlling structure including a light controlling layer including a color conversion layer including a quantum dot and a light scattering layer, and a transparent electrode layer disposed on the light controlling member such that the light emitting element and the light controlling member overlap each other in a plan view on which the base layer is disposed.

### CROSS-REFERENCE TO RELATED APPLICATION

This application claims priority to and benefits of Korean Patent Application No. 10-2024-0060943 under 35 U.S.C. § 119 filed on May 9, 2024, in the Korean Intellectual Property Office, the disclosure of which is incorporated by reference herein in its entirety.

### BACKGROUND

### 1. Technical Field

The disclosure generally relates to a display device, a method of manufacturing a display device, and an electronic device comprising a display device. More particularly, the disclosure relates to a display device having high resolution and a method of manufacturing the display device.

### 2. Description of the Related Art

Research and development of display devices have been ongoing recently due to the growing interest in information displays. As the display devices are complicated, the need for excellent and energy-efficient display devices is increased.

### SUMMARY

Embodiments provide a display device and an electronic device comprising the display device having excellent display quality such as high resolution and a method of manufacturing a display device having excellent display quality such as high resolution.

Embodiments also provide a display device, a method of manufacturing a display device, and an electronic device comprising a display device, in which process efficiency can be improved.

In accordance with an aspect of the disclosure, there is provided a display device including: a display layer including a light emitting element on a base layer; a light controlling member disposed on the display layer, the light controlling member including a light controlling layer including a color conversion layer including a quantum dot and a light scattering layer; and a transparent electrode layer disposed on the light controlling member such that the light emitting element and the light controlling member overlap each other in a plan view on which the base layer is disposed.

The display device may further include a bank disposed on the display layer, the bank including an opening. The light controlling member may be disposed in the opening.

The transparent electrode layer may overlap a central portion of the opening in a plan view.

The display device may include sub-pixel areas including a first sub-pixel area in which light of a first color is provided, a second sub-pixel area in which light of a second color is provided, and a third sub-pixel area in which light of a third color is provided. The sub-pixel areas and the bank may not overlap each other in a plan view. The transparent electrode layer may include a first transparent electrode layer disposed in the first sub-pixel area, a second transparent electrode layer disposed in the second sub-pixel area, and a third transparent electrode layer disposed in the third sub-pixel area.

The transparent electrode layer may have a size smaller than a size of each of the sub-pixel areas.

The display device may further include a base transparent electrode layer integrated with the first transparent electrode layer, the second transparent electrode layer, and the third transparent electrode layer. The base transparent electrode layer may extend in a direction in which the first transparent electrode layer, the second transparent electrode layer, and the third transparent electrode layer are spaced apart from each other.

The display device may further include: pixels, each of the pixels including the sub-pixel area, the pixels being adjacent to each other; and a connection transparent electrode layer integrated with the first transparent electrode layer, the second transparent electrode layer, and the third transparent electrode layer. The connection transparent electrode layer may electrically connect the first to third transparent electrode layers of each of the pixels to each other.

A width of the transparent electrode layer may be greater than a width of the connection transparent electrode layer.

A width of the transparent electrode layer and a width of the connection transparent electrode layer may be equal.

The display device may further include a color filter disposed on the light controlling member, wherein the transparent electrode layer is disposed between the light controlling member and the color filter in a thickness direction.

The display device may further include: a color filter disposed on the light controlling member; and an upper substrate disposed on the color filter. The transparent electrode layer may be disposed between the color filter and the upper substrate in a thickness direction.

The display device may include sub-pixel areas including a first sub-pixel area in which light of a first color is provided, a second sub-pixel area in which light of a second color is provided, and a third sub-pixel area in which light of a third color is provided. The light emitting element may include a first light emitting element disposed in the first sub-pixel area, a second light emitting element disposed in the second sub-pixel area, and a third light emitting element disposed in the third sub-pixel area. Each of the first light emitting element, the second light emitting element, and the third light emitting element may emit the light of the third color. The light controlling member may include a first color conversion layer disposed in the first sub-pixel area, a second color conversion layer disposed in the second sub-pixel area, and a light scattering layer disposed in the third sub-pixel area.

In accordance with another aspect of the disclosure, there is provided a method of manufacturing a display device, the method including: manufacturing a first panel including a display layer including a first substrate and a light emitting element disposed on the first substrate; manufacturing a second panel including a second substrate and a light controlling member disposed on the second substrate; and bonding the first panel and the second panel together, wherein the manufacturing of the second panel includes: disposing a bank and a transparent electrode layer on the second substrate; and providing an ink for forming the light controlling member in an opening formed by the bank, and wherein the providing of the ink includes supplying an alignment guide signal for the ink to the transparent electrode layer.

The providing of the ink may include forming a first polarity in the ink.

In the providing of the ink, the ink may have the first polarity, based on a triboelectric effect.

In the providing of the ink, the ink may have the first polarity by a polarity forming member generating an electric field.

The providing of the ink may include: forming a second polarity different from the first polarity in the transparent electrode layer; and guiding, by the transparent electrode layer, movement of the ink to the opening.

The transparent electrode layer may overlap the opening in a plan view. The light emitting element overlaps the transparent electrode layer and the light controlling member in a plan view. The light controlling member may include a color conversion layer including a quantum dot and a light scattering layer including a light scatterer.

In accordance with still another aspect of the disclosure, there is provided a method of manufacturing a display device, the method including: manufacturing a first panel including a display layer including a first substrate and a light emitting element disposed on the first substrate; manufacturing a second panel including a second substrate and a light controlling member disposed on the second substrate; and bonding the first panel and the second panel together, wherein the manufacturing of the second panel includes: disposing a bank on the second substrate; disposing an electric field applying assembly on a lower surface of the second substrate; and providing an ink for forming the light controlling member in an opening formed by the bank, and wherein, in the providing of the ink, an alignment guide signal for the ink is supplied to the electric field applying assembly.

The electric field applying assembly may include an electrode base and an electric field applying electrode which is disposed on the electrode base. The providing of the ink may include: forming a first polarity in the ink; and forming a second polarity different from the first polarity in the electric field applying electrode.

In accordance with still another aspect of the disclosure, an electronic device may comprise: a processor configured to transfer an input control signal; a display device configured to output an image information; and a power module configured to supply a power to the display device. The display device may comprise: a display layer disposed on a base layer, the display layer including a light emitting element; a light controlling member disposed on the display layer, the light controlling member including a light controlling layer including a color conversion layer including a quantum dot and a light scattering layer; and a transparent electrode layer disposed on the light controlling member such that the light emitting element and the light controlling member overlap each other in a plan view on which the base layer is disposed.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment of the disclosure.

FIG. 2 is a schematic cross-sectional view illustrating a display device in accordance with an embodiment of the disclosure.

FIG. 3 is a schematic view illustrating a display layer in accordance with an embodiment of the disclosure.

FIG. 4 is a schematic view illustrating a light path for each sub-pixel in accordance with an embodiment of the disclosure.

FIGS. 5 to 8 are schematic sectional views illustrating a display device in accordance with an embodiment of the disclosure.

FIGS. 9 to 12 are schematic plan views illustrating a display device in accordance with an embodiment of the disclosure.

FIGS. 13 and 14 are schematic views illustrating a process feature in which a transparent electrode layer guides movement of an ink in accordance with an embodiment of the disclosure.

FIG. 15 is a schematic flowchart illustrating a method of manufacturing a display device in accordance with an embodiment of the disclosure.

FIG. 16 is a schematic flowchart illustrating detailed steps of a step of manufacturing a second panel in accordance with an embodiment of the disclosure.

FIGS. 17 to 22 are schematic sectional views illustrating process steps of a method of manufacturing a display device in accordance with an embodiment of the disclosure.

FIG. 23 is a schematic flowchart illustrating detailed steps of the step of manufacturing the second panel in accordance with another embodiment of the disclosure.

FIGS. 24 and 25 are schematic sectional views illustrating process steps of a method of manufacturing a display device in accordance with another embodiment of the disclosure.

FIG. 26 is a schematic block diagram of an electronic device according to an embodiment.

FIG. 27 shows schematic views of various embodiments of an electronic device.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

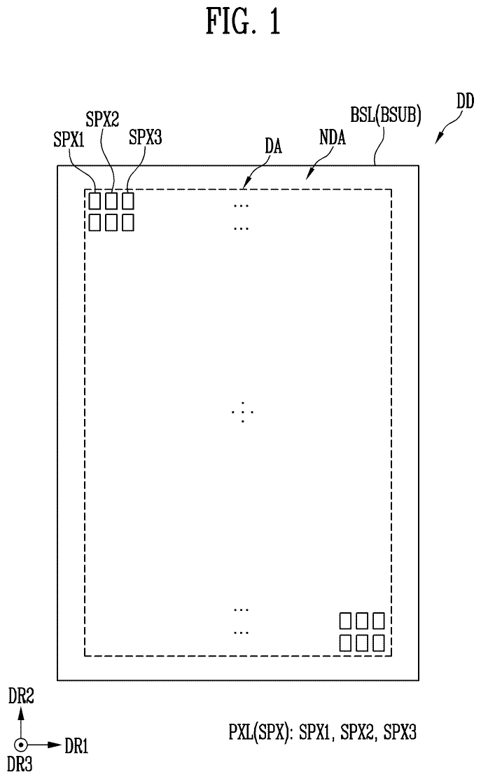

FIG. 1 is a schematic plan view illustrating a display device in accordance with an embodiment of the disclosure.

Referring to FIG. 1, the display device DD may include a base layer BSL and pixels PXL disposed on the base layer BSL. Although not shown in the drawing, the display device DD may further include a driving circuit (e.g., a scan driver and a data driver) for driving the pixels PXL, lines, and pads.

The display device DD (or the base layer BSL) may include a display area DA and a non-display area NDA. The non-display area NDA may mean an area except the display area DA. The non-display area NDA may surround at least a portion of the display area DA.

The base layer BSL may form a base surface of the display device DD. The base layer BSL may be a rigid or flexible substrate or film. For example, the base layer BSL may include a glass material. In another example, the base layer BSL may include a silicon material. In another example, the base layer BSL may include polyimide. However, the disclosure is not limited thereto.

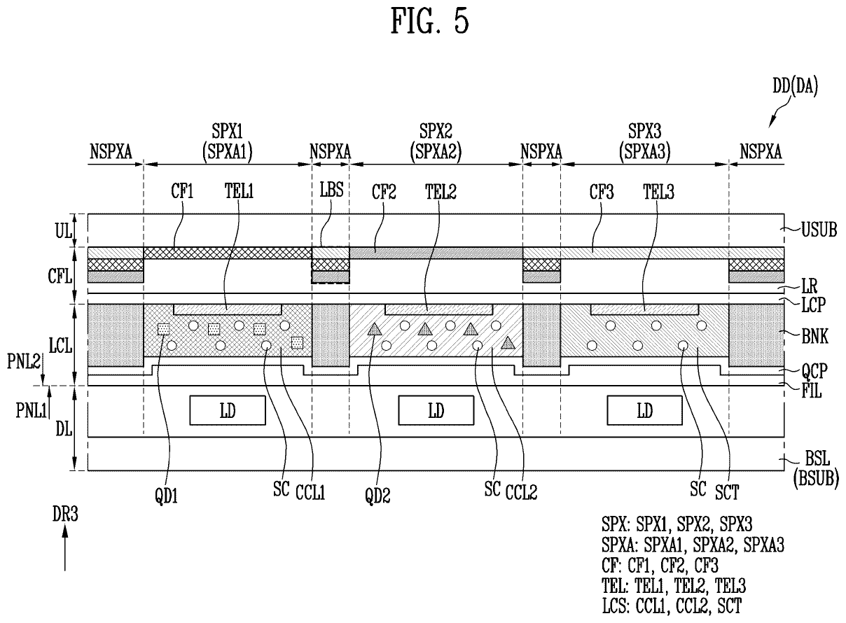

The base layer BSL may be a first substrate BSUB. The base layer BSL may include a base substrate for manufacturing a first panel PNL1 (see FIG. 5).

The display area DA may mean an area in which the pixels PXL are disposed. The non-display area NDA may mean an area in which the pixels PXL are not disposed. The driving circuit, the lines, and the pads, which are connected to the pixels PXL of the display area DA, may be disposed in the non-display area NDA.

The pixels PXL (or sub-pixels SPX) may be arranged according to a stripe arrangement structure, a PenTile® arrangement structure, or the like. However, the disclosure is not limited thereto, and various embodiments may be applied in the disclosure.

A pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form a pixel unit capable of emitting lights of various colors.

Each of the first sub-pixel SPX1, the second sub-pixel SPX2, and the third sub-pixel SPX3 may emit light of a color.

For example, the first sub-pixel SPX1 may be a red pixel emitting red light (e.g., the first color), the second sub-pixel SPX2 may be a green pixel emitting green light (e.g., the second color), and the third sub-pixel SPX3 may be a blue pixel emitting blue light (e.g., the third color). The red pixel may provide light in a wavelength band of about 600 nm to about 750 nm. The green pixel may provide light in a wavelength band of about 480 nm to about 560 nm. The blue pixel may provide light in a wavelength band of about 370 nm to about 460 nm.

A number of second sub-pixels SPX2 may be greater than a number of first sub-pixels SPXL1 and a number of third sub-pixels SPXL3. However, the color, kind, and/or number of first, second, and third sub-pixels SPX1, SPX2, and SPX3 constituting each pixel unit are not limited to a specific example. In another embodiment, a number of second sub-pixels SPX2 may be equal to a number of first sub-pixels SPXL1 and a number of third sub-pixels SPXL3, respectively.

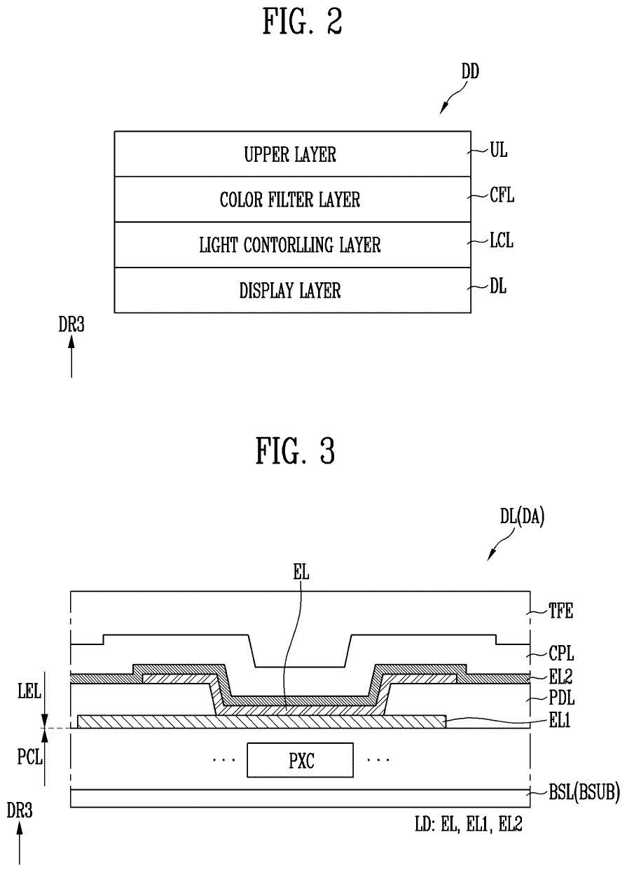

A general structure including a sectional structure of a display device DD in accordance with an embodiment of the disclosure will be described with reference to FIGS. 2 to 4.

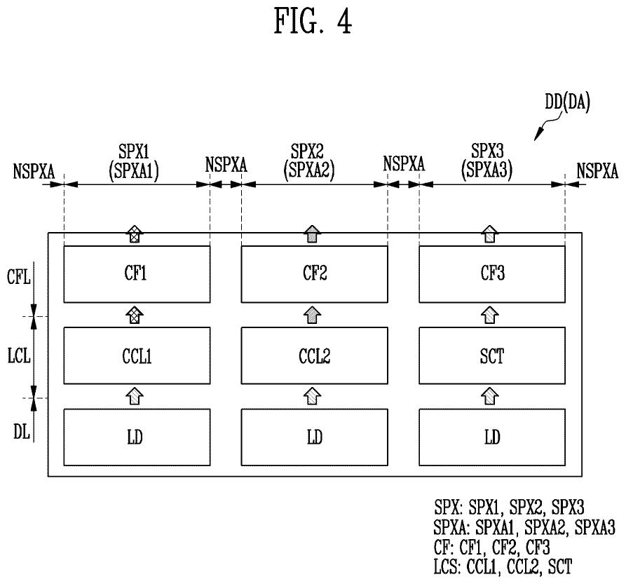

FIG. 2 is a schematic cross-sectional view illustrating a display device in accordance with an embodiment of the disclosure. FIG. 3 is a schematic view illustrating a display layer in accordance with an embodiment of the disclosure. FIG. 4 is a schematic view illustrating a light path for each sub-pixel in accordance with an embodiment of the disclosure.

Referring to FIGS. 2 to 4, the display device DD may include a display layer DL, a light controlling layer LCL, a color filter layer CFL, and an upper layer UL. For example, the light controlling layer LCL may be dispose on the display layer DL, the color filter layer CFL may be disposed on the light controlling layer LCL, and the upper layer UL may be disposed on the color filter layer CFL along a third direction DR3 (e.g., display direction or thickness direction).

The display layer DL may be configured to emit light. The display layer DL may form a base on which the light controlling layer LCL is disposed.

The display layer DL may include a pixel-circuit layer PCL including a base layer BSL and a light-emitting-element layer LEL including a light emitting element LD, thereby forming a pixel PXL.

The base layer BSL may form a base on which a pixel circuit PXC is disposed. The pixel circuit PXC may be disposed on the base layer BSL to drive the light emitting element LD. The pixel-circuit layer PCL may include conductive layers and insulating layers, and the conductive layers may form the pixel circuit PXC. The pixel circuit PXC may include circuit elements capable of driving a sub-pixel SPX (or the light emitting element LD). The circuit elements may include a driving transistor, and include an additional transistor and capacitors.

The light-emitting-element layer LEL may be disposed on the pixel-circuit layer PCL along the third direction DR3. The light emitting elements LEL may include the light emitting element LD.

As depicted in FIG. 3, the light emitting element LD may include an Organic Light Emitting Diode (OLED) including an organic material. FIG. 3 schematically illustrates an embodiment in which the light emitting element LD is an OLED, and schematically illustrates a sectional structure of the display layer DL including the pixel-circuit layer PCL and the light-emitting-element layer LEL as a sectional structure of the display device DD in a display area DA.

The light-emitting-element layer LEL may further include a pixel defining layer PDL, a capping layer CPL, and an encapsulation layer TFE.

The light emitting element LD may be disposed on the pixel-circuit layer PCL. The light emitting element LD may include a first light emitting element included in a first sub-pixel SPX1, a second light emitting element included in a second sub-pixel SPX2, and a third light emitting element included in a third sub-pixel SPX3.

The light emitting element LD may include a first electrode EL1, a light emitting unit EL, and a second electrode EL2. For example, the first electrode EL1 may be disposed on the pixel-circuit layer PCL, the light emitting unit EL may be disposed on the first electrode EL1, and the second electrode EL2 may be disposed on the light emitting unit EL. The light emitting unit EL may be disposed in an area defined by the pixel defining layer PDL. A surface of the light emitting unit EL may be electrically connected to the first electrode EL1, and another surface of the light emitting unit EL may be electrically connected to the second electrode EL2.

The first electrode EL1 may be an anode electrode of the light emitting unit EL, and the second electrode EL2 may be a cathode electrode of the light emitting unit EL. The first electrode EL1 and the second electrode EL2 may include a conductive material. For example, the conductive material may include at least one selected from the group consisting of gold (Au), silver (Ag), aluminum (Al), molybdenum (Mo), chromium (Cr), titanium (Ti), nickel (Ni), neodymium (Nd), copper (Cu), and platinum (Pt). In another example, The conductive material may include at least one selected from the group consisting of silver nano wire (AgNW), Indium Tin Oxide (ITO), Indium Zinc Oxide (IZO), Indium Gallium Zinc Oxide (IGZO), Antimony Zinc Oxide (AZO), Indium Tin Zinc Oxide (ITZO), Zinc Oxide (ZnO), Tin Oxide (SnO₂), carbon nano tube, and graphene. However, the disclosure is not limited thereto.

The light emitting unit EL may emit light based on an electrical signal provided from the anode electrode (e.g., the first electrode EL1) and the cathode electrode (e.g., the second electrode EL2).

The light emitting unit EL may emit light of a third color. The light emitting unit EL may include a multi-layer structure. For example, the light emitting unit EL may include multiple light emitting structures, and each of the light emitting structures includes a hole transport unit, a light emitting layer (or light generation layer), and an electron transport unit. Each of the layers forming the light emitting structure may include an organic material. Each of the layers forming the light emitting structure may further include a metal-containing compound, an inorganic material such as a quantum dot, or the like.

The hole transport unit may include a multi-layer structure having multiple layers including different materials. For example, the hole transport unit may include at least one of a hole injection layer and a hole transport layer. The hole transport unit may further include a light emitting auxiliary layer, an electron blocking layer, and the like. For example, the hole transport unit may have a multi-layer structure of the hole injection layer/the hole transport layer, the hole injection layer/the hole transport layer/the light emitting auxiliary layer, the hole injection layer/the light emitting auxiliary layer, the hole transport layer/the light emitting auxiliary layer, the electron blocking layer/the hole injection layer/the hole transport layer, hole transport layers which are sequentially disposed and include different materials, the hole injection layer/the hole transport layer/the electron blocking layer, or the like. However, the disclosure is not limited to a specific example.

The light emitting layer may include a material capable of emitting light of a color. The light emitting layer may include a host and a dopant. The host of the light emitting layer is a light emitting material capable of capturing carriers (electrons and holes) for generating light, and may induce excitons to be efficiently generated. The dopant of the light emitting layer may include a phosphorescent dopant and a fluorescent dopant. However, examples of the dopant are not particularly limited. For example, the dopant may include an organic material. The dopant may also include a metal complex and the like.

The electron transport unit may include a multi-layer structure having multiple layers including different materials. The electron transport unit may include at least one of an electron injection layer and an electron transport layer. The electron transport unit may further include an electron control layer, an electron buffer layer, a hole blocking layer, and the like. For example, the electron transport unit may have a multi-layer structure of the electron transport layer/the electron injection layer, the hole blocking layer/the electron transport layer/the electron injection layer, the electron control layer/the electron transport layer/the electron injection layer, the electron buffer layer/the electron transport layer/the electron injection layer, or the like. However, the disclosure is not limited to a specific example.

The pixel defining layer PDL may be disposed on the pixel-circuit layer PCL to define a position at which the light emitting unit EL. The pixel defining layer PDL may include an organic material. For example, the pixel defining layer PDL may include at least one selected from the group consisting of acrylic resin, epoxy resin, phenolic resin, polyamide resin, and polyimide resin. However, the disclosure is not limited thereto. In another embodiment, the pixel defining layer PDL may include an inorganic material. For example, the pixel defining layer PDL may include at least one of silicon oxide (SiOₓ) and silicon nitride (SiNₓ). The pixel defining layer PDL may have a multi-layer structure in which a layer including silicon oxide (SiOₓ) and a layer including silicon nitride (SiNₓ) are stacked.

The capping layer CPL may be disposed on the second electrode EL2 along the third direction DR3. The capping layer CPL may cap the second electrode EL2. The capping layer CPL may include an inorganic material.

The encapsulation layer TFE may be disposed on the light emitting element LD (e.g., the second electrode EL2). The encapsulation layer TFE may cancel a step difference generated by the light emitting element LD and the pixel defining layer PDL. The encapsulation layer TFE may include multiple insulating layers covering the light emitting element LD. The encapsulation layer TFE may have a structure in which an inorganic layer and an organic layer are alternately stacked. The encapsulation layer TFE may be a thin film encapsulation layer.

In another example, the light emitting element LD may be an inorganic light emitting diode including an inorganic material. In case that the light emitting element LD includes an inorganic material, the light emitting element LD may emit light including a light component of the third color (e.g., blue light).

The light controlling layer LCL may be disposed on the display layer DL (e.g., the light-emitting-element layer LEL). For example, the light controlling layer LCL may be disposed on an upper side of the display layer DL along the third direction DR3 (e.g., display direction or thickness direction).

The light controlling layer LCL may change a color of applied light and scatter the applied light. For example, the light controlling layer LCL may include light controlling structures (or light controlling members) LCS (see FIG. 4). The light controlling structure LCS may include color conversion layers CCL1 and CCL2 and a light scattering layer SCT (see FIG. 4).

The color filter layer CFL may be disposed on the light controlling layer LCL. For example, the color filter layer CFL may be disposed on an upper side of the light controlling layer LCL along the third direction DR3.

The color filter layer CFL may include color filters CF (see FIG. 4) which allow light of one color to be selectively transmitted therethrough.

The upper layer UL may be disposed on the color filter layer CFL. For example, the upper layer UL may be disposed on an upper side of the color filter layer CFL along the third direction DR3.

The upper layer UL may include a second substrate USUB (see FIG. 5). The second substrate USUB may be an upper substrate. The second substrate USUB may include a base substrate for manufacturing a second panel PNL2 (see FIG. 5).

Structural features in which the display device DD implements a full-color display will be described with reference to FIG. 4. In FIG. 4, descriptions of portions overlapping the above-described portions will be simplified or will not be repeated.

FIG. 4 is a schematic block diagram illustrating a path of light for each sub-pixel, which the display device provides in accordance with an embodiment of the disclosure.

Referring to FIG. 4, the display device DD may include a sub-pixel area SPXA and a non-sub-pixel area NSPXA.

The sub-pixel area SPXA may be an area formed by a sub-pixel SPX so that light of a color is provided. The non-sub-pixel area NSPXA may be an area interposed between adjacent sub-pixel areas SPXA, and may be an area in which no light of a color is provided.

The sub-pixel area SPXA may include a first sub-pixel area SPXA1 in which light of a first color is provided as an area defined by the first sub-pixel SPX1, a second sub-pixel area SPXA2 in which light of a second color is provided as an area defined by the second sub-pixel SPX2, and a third sub-pixel area SPXA3 in which light of a third color is provided as an area defined by the third sub-pixel SPX3.

The light controlling layer LCL and the color filter layer CFL may be sequentially disposed on the display layer DL to form the first to third sub-pixels SPX1 to SPX3.

A light emitting element LD may be disposed in each of the first to third sub-pixel areas SPXA1 to SPXA3. The light emitting elements LD disposed in the first to third sub-pixel areas SPXA1 to SPXA3 may emit light of a same third color (e.g., blue).

The light controlling layer LCL may include a first color conversion layer CCL1 disposed in the first sub-pixel area SPXA1, a second color conversion layer CCL2 disposed in the second sub-pixel area SPXA2, and a light scattering layer SCT disposed in the third sub-pixel area SPXA3.

The color filter layer CFL may include a color filter CF which includes a first color filter CF1 disposed in the first sub-pixel area SPXA1, a second color filter CF2 disposed in the second sub-pixel area SPXA2, and a third color filter CF3 disposed in the third sub-pixel area SPXA3.

In the first sub-pixel area SPXA1, light emitted from the light emitting element LD may be provided as light of the first color (e.g., red) after being converted through the first color conversion layer CCL1, and the light of the first color (e.g., red) may be viewed in the first sub-pixel area SPXA1 after being transmitted through the first color filter CF1.

In the second sub-pixel area SPXA2, light emitted from the light emitting element LD may be provided as light of the second color (e.g., green) after being converted through the second color conversion layer CCL2, and the light of the second color (e.g., green) may be viewed in the second sub-pixel area SPXA2 after being transmitted through the second color filter CF2.

In the third sub-pixel area SPXA3, light of the third color (e.g., blue) may be viewed after light emitted from the light emitting element LD is transmitted through the light scattering layer SCT and the third color filter CF3.

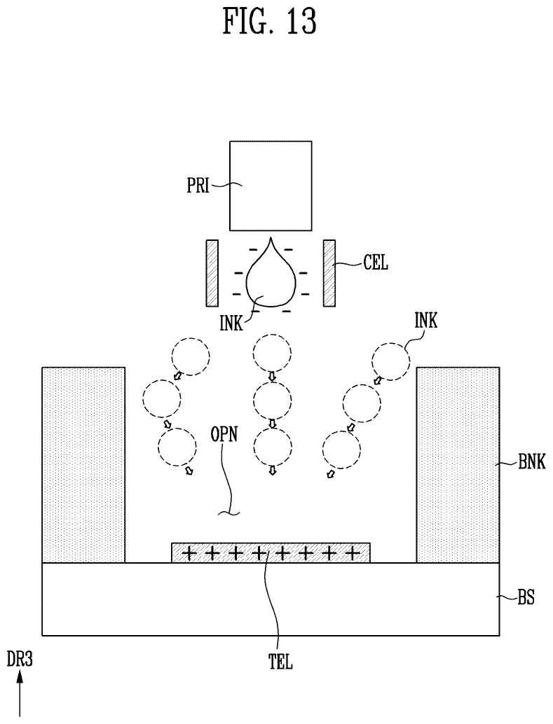

Accordingly, the display device DD in accordance with the embodiment of the disclosure can implement a full-color display. The light controlling structure LCS may be manufactured based on an inkjet printing process. In a method of manufacturing the display device DD in accordance with the embodiment of the disclosure, in case that the inkjet printing process is performed, a process step for guiding movement of an ink INK (see FIG. 13) may be applied. Accordingly, process performance can be excellent, and high-resolution characteristics can be provided. Thus, the display device DD having excellent display quality can be manufactured. This will be described in detail later. However, the disclosure is not limited thereto. In another example, the light controlling structure LCS may be manufactured by a different manufacturing process.

Hereinafter, a display device DD in accordance with an embodiment of the disclosure will be described with reference to FIGS. 5 to 14. In FIGS. 5 to 14, descriptions of portions overlapping the above-described portions will be simplified or will not be repeated.

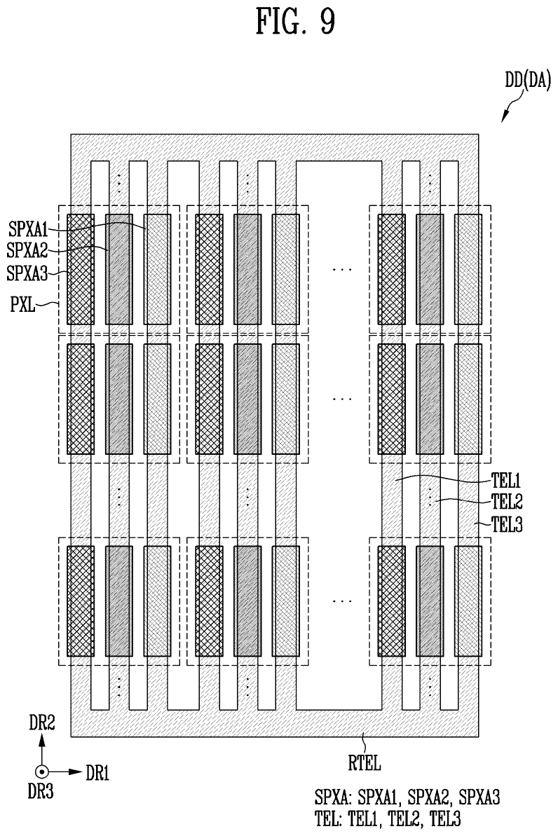

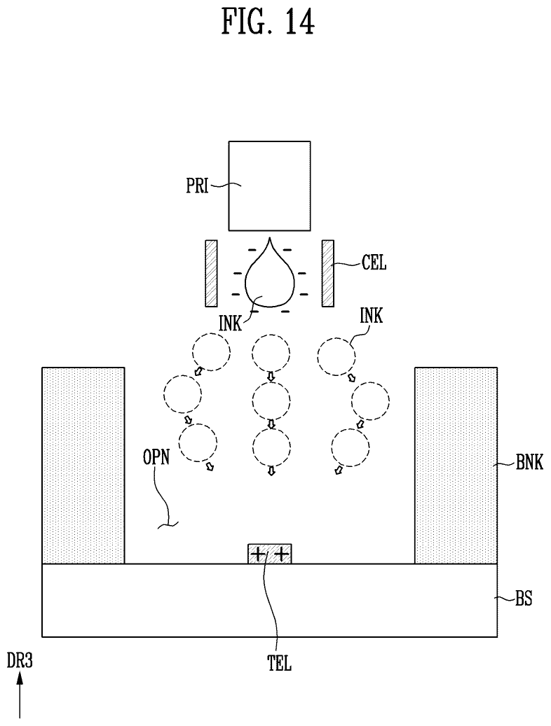

FIGS. 5 to 8 are schematic sectional views illustrating a display device in accordance with an embodiment of the disclosure. FIGS. 9 to 12 are schematic plan views illustrating a display device in accordance with an embodiment of the disclosure. FIGS. 13 and 14 are schematic views illustrating a process feature in which a transparent electrode layer guides movement of an ink in accordance with an embodiment of the disclosure.

Layers of the display device DD may be manufactured on a same substrate, or be manufactured on different substrates and then bonded together.

For example, a first panel PNL1 may be manufactured by forming a display layer DL disposed on a first substrate BSUB, a second panel PNL2 may be manufactured by forming a color filter layer CFL and a light controlling layer LCL disposed on a second substrate USUB, and the first panel PNL1 and the second panel PNL2 may be bonded to each other by interposing a filling layer FIL between the first panel PNL1 and the second panel PNL2. Accordingly, the display device DD may be provided.

The display device DD may include a transparent electrode layer TEL. The transparent electrode layer TEL may be a component for forming an alignment guide signal applied to an inkjet printing process for forming at least a portion of the light controlling layer LCL included in the display device DD.

The light controlling layer LCL may be a component formed on the lower surface the color filter layer CFL, and include a bank BNK, a light controlling structure LCS, a lower capping layer QCP, and the filling layer FIL. The light controlling structure LCS may include color conversion layers CCL1 and CCL2 and a light scattering layer SCT.

The light controlling layer LCL may be formed on the second substrate USUB and be manufactured to be included in the second panel PNL2. Accordingly, the light controlling layer LCL may be disposed on the lower surface of the color filter layer CFL.

The bank BNK may be disposed on the display layer DL, and be disposed on the lower surface of the color filter layer CFL. For example, the bank BNK may be disposed on an optical capping layer LCP. Thus, the bank BNK may be interposed between the optical capping layer LCP and the lower capping layer QCP along the third direction DR3.

The bank BNK may be disposed between adjacent sub-pixel areas SPXA in a plan view. For example, the bank BNK may overlap a non-sub-pixel area NSPXA in a plan view.

The bank BNK may surround at least a portion of one area. For example, the bank BNK may surround at least a portion of an area for forming a sub-pixel area SPXA, and protrude in the thickness direction of a base layer BSL (e.g., the third direction DR3). Accordingly, the bank BNK may form a space (e.g., an opening OPN, see FIG. 13) in which the color conversion layers CCL1 and CCL2 and the light scattering layer SCT may be disposed (e.g., accommodated).

A plane defined in this specification is a plane extending in a first direction DR1 and a second direction DR2, and may be defined with respect to a plane on which the base layer BSL is disposed. The third direction DR3 may be the thickness direction of the base layer BSL. The third direction DR3 may be a light output direction of the display device DD.

The bank BNK may include various materials. For example, the bank BNK may include an organic material. The bank BNK may include at least one selected from the group consisting of acrylic resin, epoxy resin, phenolic resin, polyamide resin, and polyimide resin. However, the disclosure is not limited thereto.

The light controlling structure LCS may be disposed in an area (e.g., the opening OPN, see FIG. 13) surrounded by the bank BNK. The light controlling structure LCS may be manufactured based on the inkjet printing process.

The color conversion layers CCL1 and CCL2 may be disposed on the lower surface of the color filter layer CFL. For example, the color conversion layers CCL1 and CCL2 may be disposed on the optical capping layer LCP.

A first color conversion layer CCL1 may be disposed in an area surrounded by the bank BNK in a first sub-pixel area SPXA1. The first color conversion layer CCL1 may include a first quantum dot QD1 capable of converting light of a third color (e.g., blue), which a light emitting element LD provides, into light of a first color (e.g., red) to form a first sub-pixel SPX1. The first quantum dot QD1 may emit light of the first color by absorbing light of the third color (e.g., blue) and shifting a wavelength of the light of third color (e.g., blue) according to energy transition. The first quantum dot QD1 may be provided to be dispersed in a matrix layer such as an organic material.

A second color conversion layer CCL2 may be disposed in an area surrounded by the bank BNK in a second sub-pixel area SPXA1. The second color conversion layer CCL2 may include a second quantum dot QD2 capable of converting light of the third color (e.g., blue), which a light emitting element LD provides, into light of a second color (e.g., green) to form a second sub-pixel SPX2. The second quantum dot QD2 may emit light of the second color by absorbing light of the third color (e.g., blue) and shifting a wavelength of the light of third color according to energy transition. The second quantum dot QD2 may be provided to be dispersed in a matrix layer such as an organic material.

The light scattering layer SCT may be disposed in an area surrounded by the bank BNK in a third sub-pixel area SPXA3. The light scattering layer SCT may be a layer provided to improve light output efficiency (e.g., luminance) and to improve viewing angle characteristics. For example, the light scattering layer SCT may include a light scatterer SC. The light scatterer SC may be provided to be dispersed in a matrix such as an organic material (e.g. a transparent organic material). The light scatterer SC may include various light scattering particles. For example, the light scatterer SC may include at least one of titanium oxide (TiOₓ) and silica (SiOₓ) (e.g., silica bead, hollow silica, or the like). However, the disclosure is not limited thereto. The light scatterer SC may be included in the first color conversion layer CCL1 and the second color conversion layer CCL2 in addition to the light scattering layer SCT.

The lower capping layer QCP may passivate the color conversion layers CCL1 and CCL2, the light scattering layer SCT, and the bank BNK. The lower capping layer QCP may include an inorganic material.

The transparent electrode layer TEL may be disposed in the sub-pixel area SPXA. The transparent electrode layer TEL may overlap the light emitting layer LD in a plan view. The transparent electrode layer TEL may overlap the light controlling structure LCS in a plan view. The transparent electrode layer TEL may be disposed on the light controlling structure LCS. The transparent electrode layer TEL may be disposed between the second substrate USUB and the light controlling structure LCS.

The transparent electrode layer TEL may include a first transparent electrode layer TEL1, a second transparent electrode layer TEL2, and a third transparent electrode layer TEL3.

The first transparent electrode layer TEL1 may be disposed in the first sub-pixel area SPXA1. The first transparent electrode layer TEL1 may overlap the first color conversion layer CCL1 in a plan view. The second transparent electrode layer TEL2 may be disposed in the second sub-pixel area SPXA2. The second transparent electrode layer TEL2 may overlap the second color conversion layer CCL2 in a plan view. The third transparent electrode layer TEL3 may be disposed in the third sub-pixel area SPXA3. The third transparent electrode layer TEL3 may overlap the light scattering layer SCT in a plan view.

In a plan view, each of the first to third transparent electrode layers TEL1 to TEL3 may be disposed on each of central portions of the first to third sub-pixel areas SPXA1 to SPXA3, respectively.

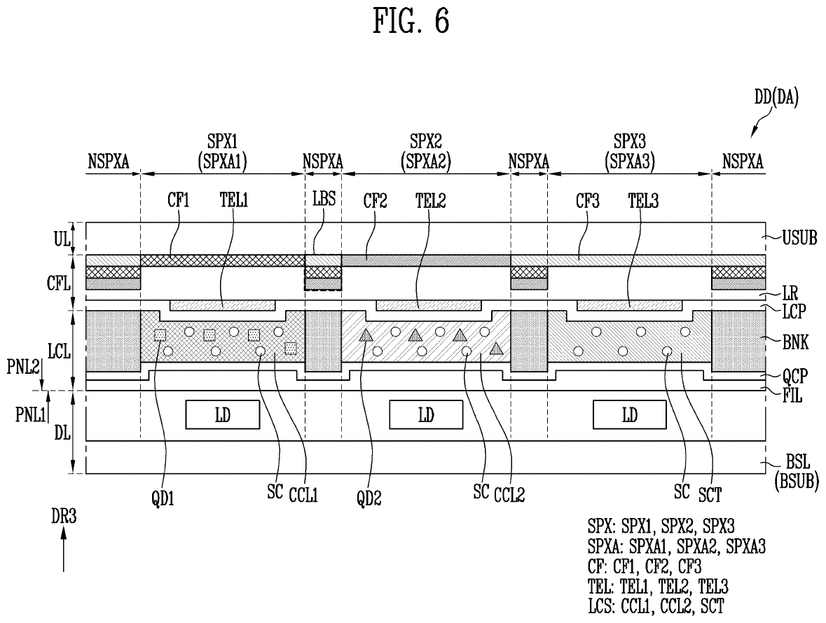

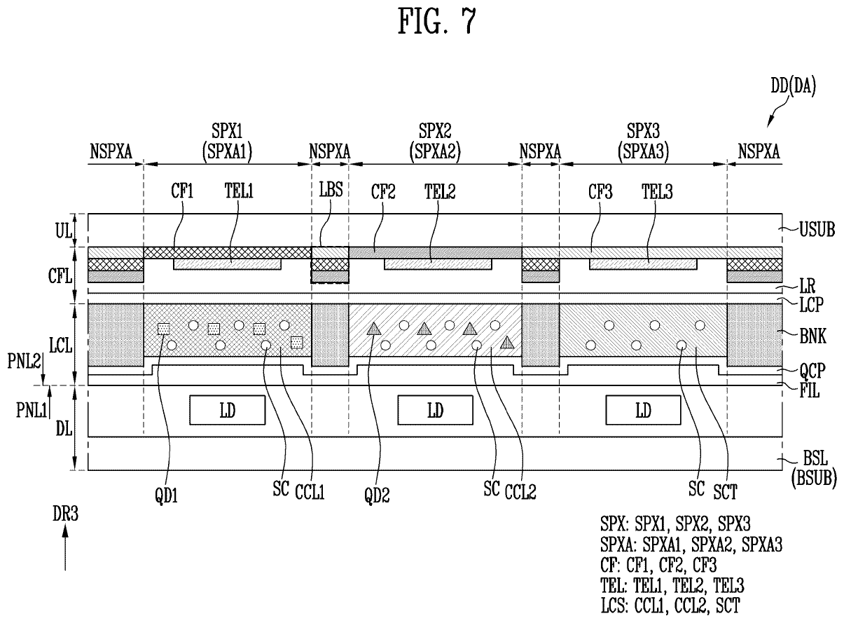

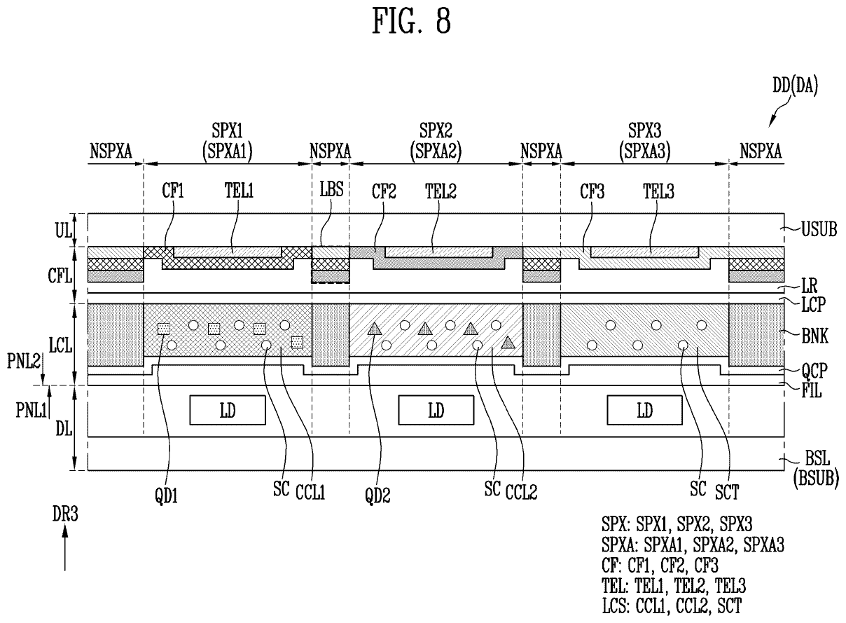

The transparent electrode layer TEL may be disposed at various positions. For example (see FIG. 5), the transparent electrode layer TEL may be disposed between color filters CF and the light controlling structure LCS. The transparent electrode layer TEL may be disposed (e.g., directly disposed) on the optical capping layer LCP. In another example (see FIG. 6), the transparent electrode layer TEL may be disposed between the optical capping layer LCP and an optical layer LR. In another example (see FIG. 7), the transparent electrode layer TEL may be disposed between the color filters CF and the optical layer LR. In another example (see FIG. 8), the transparent electrode layer TEL may be disposed between the second substrate USUB and the color filters CF.

As depicted in FIG. 9, the display device DD may further include a base transparent electrode layer RTEL. The base transparent electrode layer RTEL may electrically connect the first to third transparent electrode layers TEL1 to TEL3 to each other. The first to third transparent electrode layers TEL1 to TEL3 may be integrated with each other. The base transparent electrode layer RTEL may extend in a direction in which the first to third transparent electrode layers TEL1 to TEL3 are spaced apart from each other. For example, the first to third transparent electrode layers TEL1 to TEL3 may be spaced apart from each other in the first direction DR1, each of the first to third transparent electrode layers TEL1 to TEL3 may extend in the second direction DR2 perpendicular to the first direction DR1, and the base transparent electrode layer RTEL may extend in the first direction DR1. Accordingly, the first to third transparent electrode layers TEL1 to TEL3 may be electrically connected to each other.

Accordingly, the first to third transparent electrode layers TEL1 to TEL3 may be sequentially arranged in the display area DA. The first to third transparent electrode layers TEL1 to TEL3 in each pixel PXL may overlap the first to third sub-pixel areas SPXA1 to SPXA3, respectively.

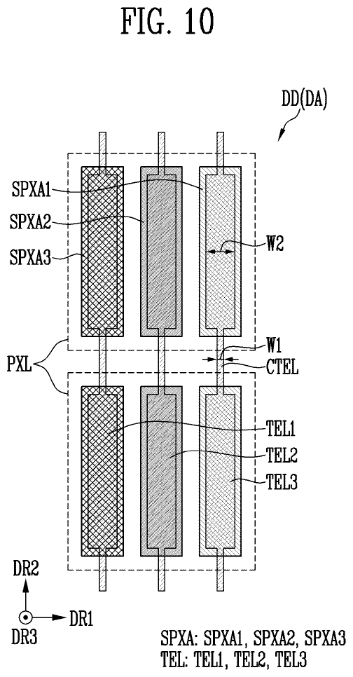

As depicted in FIGS. 10 to 12, the display device DD may further include a connection transparent electrode layer CTEL extending along the second direction DR2. The connection transparent electrode layer CTEL may electrically connect the first to third transparent electrode layers TEL1 to TEL3 to each other. The first to third transparent electrode layers TEL1 to TEL3 may be integrated with each other. The connection transparent electrode layer CTEL may electrically connect the first to third transparent electrode layers TEL1 to TEL3 of each of pixels PXL adjacent to each other.

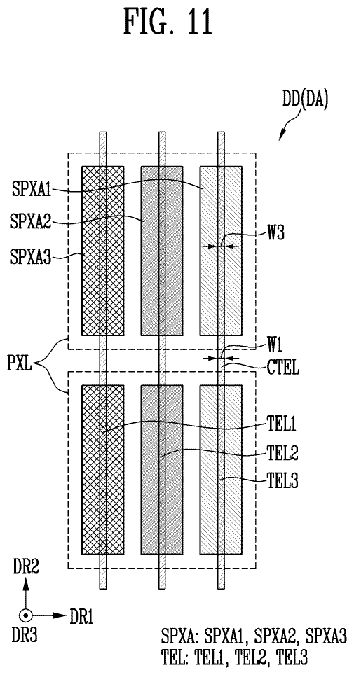

As depicted in FIG. 10, the connection transparent electrode layer CTEL may have a width W1 (along the first direction DR1) relatively narrower than a width W2 (along the first direction DR1) of each of the first to third transparent electrode layers TEL1 to TEL3. However, the disclosure is not limited thereto. For example, as depicted in FIG. 11, the width W1 of the connection transparent electrode layer CTEL may be equal to a width W3 of each of the first to third transparent electrode layers TEL1 to TEL3.

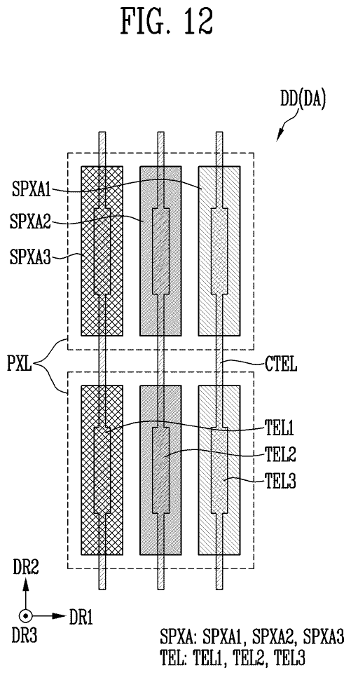

As depicted in FIG. 10, the first to third transparent electrode layers TEL1 to TEL3 may have a size corresponding to (e.g., substantially equal to) a size of the first to third sub-pixel areas SPXA1 to SPXA3. In another example, as depicted in see FIG. 12, the first to third transparent electrode layers TEL1 to TEL3 may have a size smaller than a size of the first to third sub-pixel areas SPXA1 to SPXA3. For example, the first to third transparent electrode layers TEL1 to TEL3 may be disposed to have a relatively small size at a position corresponding to the central portion of each of the first to third sub-pixel areas SPXA1 to SPXA3.

The transparent electrode layer TEL may include a transparent conductive material. For example, the transparent electrode layer TEL may include at least one selected from the group consisting of silver nano wire (AgNW), Indium Tin Oxide (ITO), Indium Zinc Oxide (IZO), Indium Gallium Zinc Oxide (IGZO), Antimony Zinc Oxide (AZO), Indium Tin Zinc Oxide (ITZO), Zinc Oxide (ZnO), Tin Oxide (SnO₂), carbon nano tube, and graphene. Accordingly, in case that the transparent electrode layer TEL is disposed upwardly of the light controlling structure LCS with respect to a display direction of the display device DD, a light output path can be suitably defined.

Meanwhile, as described above, the light controlling structure LCS may be manufactured based on the inkjet printing process. The transparent electrode layer TEL may guide movement of an ink INK (see FIG. 13) during the inkjet printing process. This will be described with reference to FIGS. 13 and 14.

FIGS. 13 and 14 schematically illustrate an inkjet printing process of supplying an ink INK in an opening OPN formed by the bank BNK. For convenience of description, layers disposed under the bank BNK to form a base on which the bank BNK is disposed are designated as a base member BS. Also, for convenience of description, the inkjet printing process is described based on a structure in which the transparent electrode TEL is schematically disposed on the base member BS to overlap the opening OPN.

The ink INK may be supplied to the opening OPN to form the light controlling structure LCS. For example, to perform the inkjet printing process, the ink INK including a material for forming the light controlling structure LCS and a solvent (e.g., an organic solvent) may be provided, and a printing apparatus PRI including a nozzle portion for discharging the ink INK may be prepared. The printing apparatus PRI may supply the ink INK to the opening OPN.

A polarity forming member CEL may be further prepared so as to perform the inkjet printing process.

The polarity forming member CEL may form a polarity in the ink INK. For example, the ink INK may be charged by the polarity forming member CEL.

The ink INK may have a negative polarity or a positive polarity by the polarity forming member CEL, but the disclosure is not limited to a specific example. Hereinafter, for convenience of description, an embodiment in which the ink INK has a negative polarity in the inkjet printing process will be mainly described.

The polarity forming member CEL may form a polarity in the ink INK, based on a triboelectric effect. For example, the polarity forming member CEL may be disposed adjacent to a moving path of the ink INK. For example, the polarity forming member CEL may be formed at the nozzle portion of the printing apparatus PRI. As the ink INK moves downward, the ink INK and the polarity forming member CEL may have different polarity due to the triboelectric effect. The kind and magnitude of the polarity of the ink INK may vary according to a solvent included in the ink INK and a material of the polarity forming member CEL. For example, in case that the polarity forming member CEL includes a plastic material such as polyvinyl chloride (PVC) or polystyrene (PS), the ink INK may have a relatively positive polarity in some embodiments. In another example, in case that the polarity forming member CEL includes a glass material or the like, the ink INK may have a relatively negative polarity in some embodiments. However, it is apparent that the disclosure is not limited to a specific example. The kind and magnitude of the polarity which the ink INK has may be differently defined according to the triboelectric effect caused by the material such as the solvent included in the ink INK and the material of the polarity forming member CEL.

In another example, the polarity forming member CEL may form an electric field as a voltage is supplied thereto, and accordingly, a polarity may be formed in the ink INK. For example, the polarity forming member CEL may be a charging electrode. The polarity forming member CEL may be formed in at least a portion of the path through which the ink INK is provided. For example, the polarity forming member CEL may be formed inside the printing apparatus PRI or be formed outside of the printing apparatus PRI. In case that a polarity is formed in the ink INK as the polarity forming member CEL forms an electric field, the ink INK may have a positive polarity or have a negative polarity in some embodiments.

The ink INK which is supplied by the printing apparatus PRI and has a polarity by the polarity forming member CEL may be supplied to the opening OPN, and the movement (or the moving path) of the ink INK may be changed by the transparent electrode layer TEL.

For example, the transparent electrode layer TEL may be disposed to overlap the opening OPN, and therefore, the ink INK may be guided to be supplied into the opening OPN. As depicted in FIG. 14, a width of the transparent electrode layer TEL may be decreased. A discharge path of the ink INK may further face a central portion of the opening OPN.

In the inkjet printing process, the transparent electrode layer TEL may have a polarity different from the polarity of the ink INK. For example, an alignment guide signal may be supplied to the transparent electrode layer TEL, and the transparent electrode layer TEL may have a polarity. In case that the ink INK has a positive polarity, the alignment guide signal may be supplied to the transparent electrode layer TEL to have a negative polarity. In case that the ink INK has a negative polarity, the alignment guide signal may be supplied to the transparent electrode layer TEL to have a positive polarity.

In case that the ink INK is supplied adjacent to the opening OPN, the moving path of the ink INK may be guided to roughly face the transparent electrode layer TEL. For example, in case that the moving path of the ink INK is slightly spaced apart from the position of the opening OPN, the ink INK may be moved to face the opening OPN. Accordingly, a margin for an ink supply area defined to supply the ink INK into the opening OPN can be secured, and thus process efficiency, process performance, and the like can be improved.

In case that the ink INK is discharged in the same range, the size of the opening OPN, into which the ink INK can be suitably supplied, can be decreased. For example, since the size of the sub-pixel areas SPXA can be decreased, the display device DD having high resolution can be manufactured.

It is desirable that the ink INK including different materials should be supplied to different adjacent openings OPN. Since the moving path of the ink INK can be guided to face the transparent electrode layer INK, the ink INK may be suitably supplied to a corresponding opening OPN even the width of the bank BNK is decreased. Accordingly, a risk that the ink INK will be discharged to an area instead of an intended opening OPN is reduced so that a risk that a color mixture risk between the sub-pixels SPX can be reduced.

The color filter layer CFL may be disposed on the light controlling layer LCL. The color filter layer CFL may include the color filters CF, the optical layer LR, and the optical capping layer LCP.

For example, the color filter layer CFL may be formed on the second substrate USUB and manufactured to include the second panel PNL2. Accordingly, the color filter layer CFL may be disposed on the lower surface of the upper layer UL.

The color filters CF may be disposed on the lower surface of the second substrate USUB. The color filter CF may include the first color filter CF1 for forming the first sub-pixel SPX1, the second color filter CF2 for forming the second sub-pixel SPX2, and the third color filter CF3 for forming the third sub-pixel SPX3.

The first color filter CF1 may be disposed in the first sub-pixel area SPXA1. The first color filter CF1 may include a color filter material (e.g., a dye or a pigment) for allowing light of a first color (e.g., red) to be selectively transmitted therethrough.

The second color filter CF2 may be disposed in the second sub-pixel area SPXA2. The second color filter CF2 may include a color filter material (e.g., a dye or a pigment) for allowing light of a second color (e.g., green) to be selectively transmitted therethrough.

The third color filter CF3 may be disposed in the third sub-pixel area SPXA3. The third color filter CF3 may include a color filter material (e.g., a dye or a pigment) for allowing light of a third color (e.g., blue) to be selectively transmitted therethrough.

A non-sub-pixel area NSPXA in which light of one color cannot be viewed may be formed between the sub-pixel areas SPXA. In some embodiments, in a plan view, the first color filter CF1, the second color filter CF2, and the third color filter CF3 overlap each other in the non-sub-pixel area NSPXA, thereby forming a light blocking structure LBS.

The optical layer LR may be disposed on the color filters CF. The optical layer LR may be disposed throughout the sub-pixel areas SPXA and the non-sub-pixel area NSPXA.

The optical layer LR may have a refractive index higher than a refractive index of layers forming the color filters CF. The optical layer LR may have a refractive index lower than a refractive index of the color conversion layers CCL1 and CCL2, and form a light recycling structure. The optical layer LR may include various materials to have a refractive index. For example, the optical layer LR may include various resins and hollow silica. In another example, the optical layer LR may include zirconium oxide (ZrOₓ). However, the disclosure is not limited thereto.

The optical layer LR may be designated as a low refractive layer.

The optical capping layer LCP may be disposed on the optical layer LR. The optical capping layer LCP may be disposed throughout the sub-pixel areas SPXA and the non-sub-pixel area NSPXA. The optical capping layer LCP may passivate the optical layer LR. The optical capping layer LCP may include an inorganic material.

The second substrate USUB may be disposed as a base member for manufacturing the second panel PNL2 on the color filter layer CFL.

The second substrate USUB may be a manufacturing substrate for manufacturing the second panel PNL2, and include one of the materials described above with reference to the first substrate BSUB (e.g., the base layer BSL). For example, the second substrate USUB may include a glass substrate.

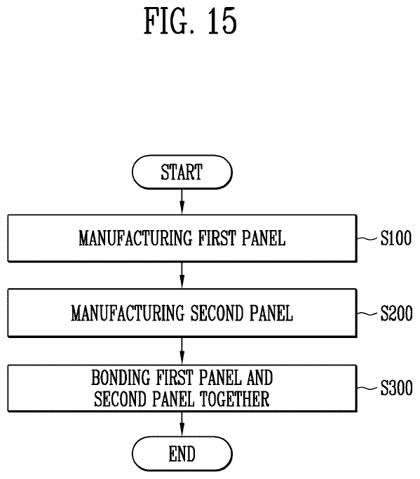

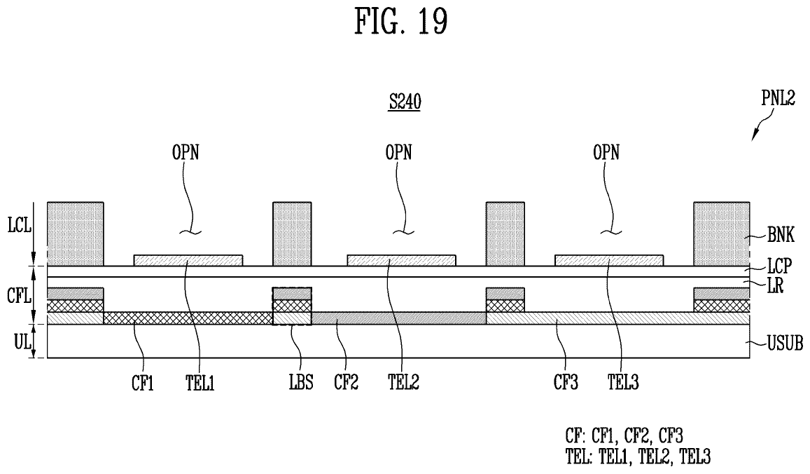

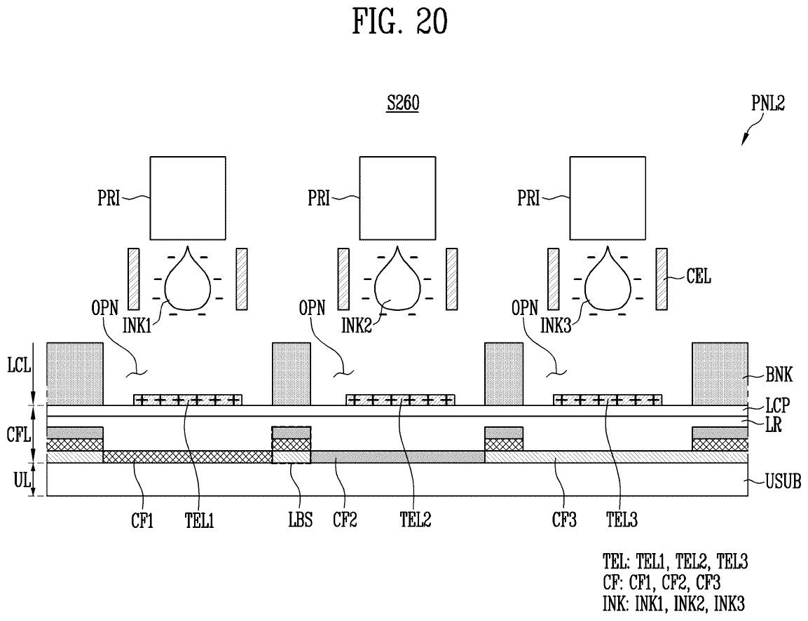

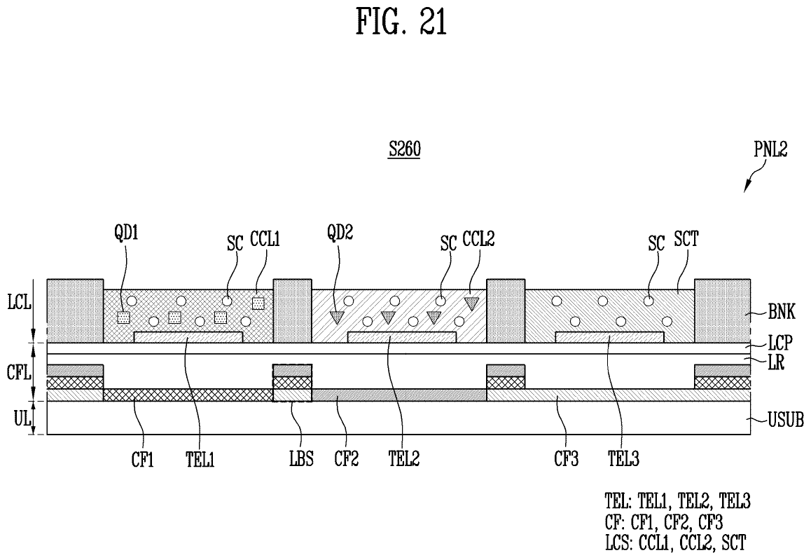

A method of manufacturing a display device DD in accordance with an embodiment will be described with reference to FIGS. 15 to 25. In FIGS. 15 to 25, descriptions of portions overlapping the above-described portions will be simplified or will not be repeated.

FIGS. 15 to 25 illustrate a method of manufacturing a display device DD, in which a first panel PNL1 and a second panel PNL2 are separately provided and then bonded to each other, thereby manufacturing the display device DD.

FIG. 15 is a schematic flowchart illustrating a method of manufacturing a display device in accordance with an embodiment of the disclosure.

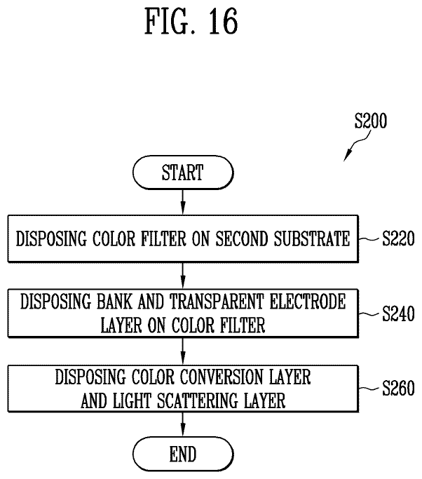

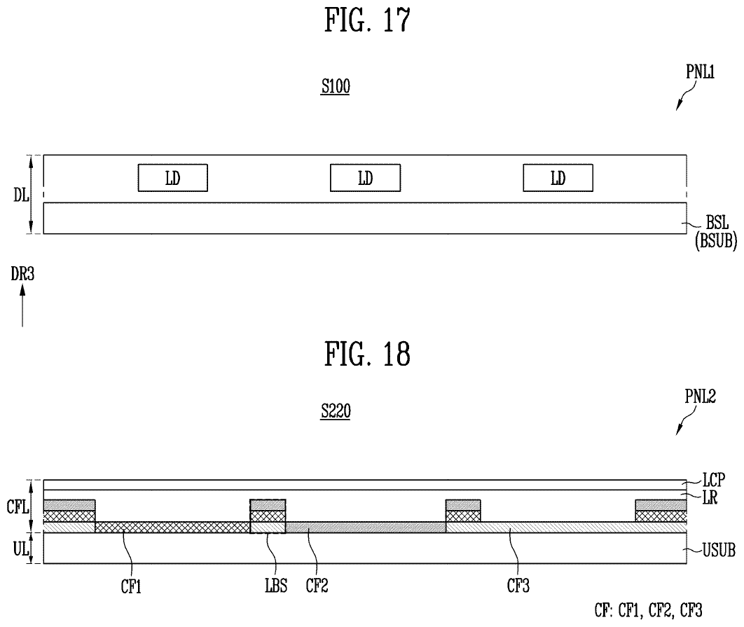

FIG. 16 is a schematic flowchart illustrating detailed steps of a step of manufacturing a second panel in accordance with an embodiment of the disclosure. FIGS. 17 to 22 are schematic sectional views illustrating process steps of a method of manufacturing a display device in accordance with an embodiment of the disclosure. For convenience of description, FIGS. 17 to 22 are schematic sectional views illustrating process steps of the sectional structure described above with reference to FIG. 5.

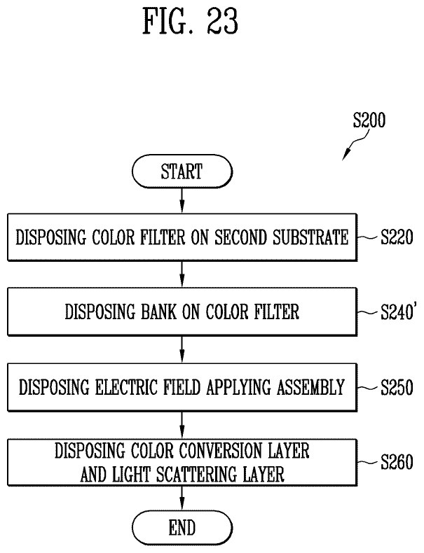

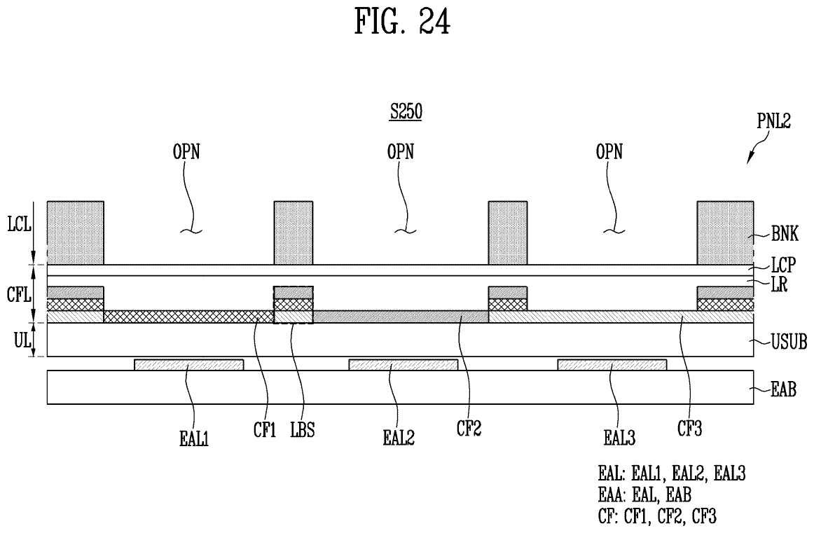

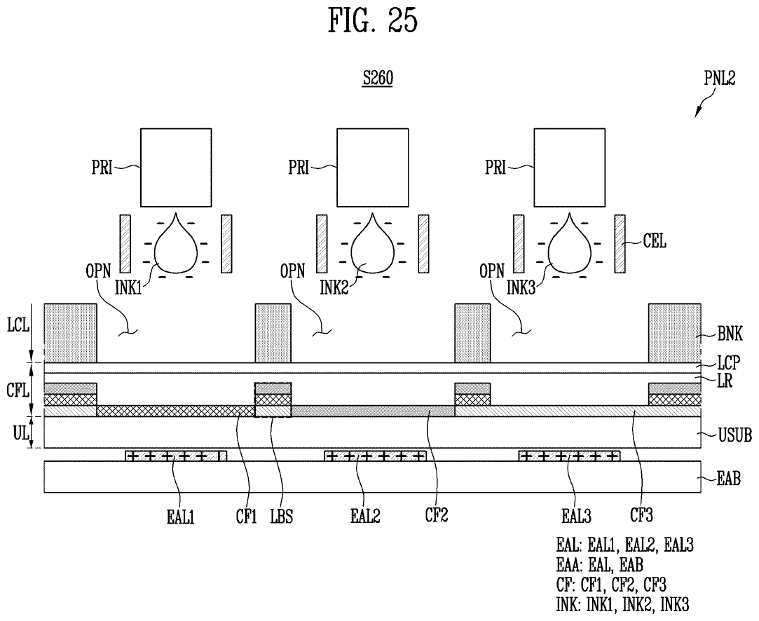

FIG. 23 is a schematic flowchart illustrating detailed steps of the step of manufacturing the second panel in accordance with another embodiment of the disclosure. FIGS. 24 and 25 are schematic sectional views illustrating process steps of a method of manufacturing a display device in accordance with another embodiment of the disclosure. For convenience of description, FIGS. 24 and 25 are schematic sectional views illustrating process steps of the sectional structure described with reference to FIG. 5, and schematically illustrate an embodiment in which the transparent electrode layer TEL is not included.

The method of manufacturing the display device DD in accordance with the embodiment of the disclosure may include step S100 of manufacturing a first panel, step S200 of manufacturing a second panel, and step S300 of bonding the first panel and the second panel together.

The step S200 of manufacturing the second panel may be performed after the step S100 of manufacturing the first panel is performed. In another example, the step S100 of manufacturing the first panel may be performed after the step S200 of manufacturing the second panel is performed. In another example, the step S100 of manufacturing the first panel and the step S200 of manufacturing the second panel may be substantially performed simultaneously. For convenience of description, the method of manufacturing the display device DD will be described based on an embodiment in which the step S200 of manufacturing the second panel is performed after the step S100 of manufacturing the first panel is performed.

Firstly, a method of manufacturing a display device DD in accordance with an embodiment of the disclosure will be described with reference to FIGS. 15 to 22. FIGS. 15 to 22 illustrate a method of manufacturing a display device DD including a transparent electrode TEL in accordance with an embodiment of the disclosure.

Referring to FIGS. 15 and 17, in the step S100 of manufacturing the first panel, the first panel PNL1 including a display layer DL may be prepared.

In this step S100, layers forming the display layer DL may be disposed on a first substrate BSUB forming a base layer BSL.

A conductive layer or an insulating layer on the first substrate BSUB and a second substrate USUB (see FIG. 18) may be formed based on a standard process for manufacturing a semiconductor device. For example, the conductive layer or the insulating layer on the first substrate BSUB and the second substrate USUB may be formed through a photolithography process, be etched through various processes (wet etching, dry etching, and the like), and be deposited through various processes (sputtering, chemical vapor deposition, and the like). However, the disclosure is not limited to a specific example.

In this step S100, a pixel-circuit layer PCL may be formed by patterning a pixel circuit PXC on the first substrate BSUB, and light emitting elements LD may be disposed on the pixel-circuit layer PCL. In this step S100, the light emitting elements LD may be disposed on the first substrate BSUB (e.g., the pixel-circuit layer PCL) through various processes.

For example, in conjunction with FIG. 3, the light emitting element LD may include an organic light emitting diode, and the light emitting elements LD may be manufactured on the first substrate BSUB through a deposition process.

Referring to FIG. 15, the step S200 of manufacturing the second panel may be performed. In conjunction with FIG. 16, the step S200 of manufacturing the second panel may include step S220 of disposing a color filter on a second substrate, step S240 of disposing a bank and a transparent electrode layer on the color filter, and step S260 of disposing a color conversion layer and a light scattering layer.

Referring to FIGS. 15, 16, and 18, in the step S220 of disposing the color filter on the second substrate, color filters CF may be sequentially disposed on the second substrate USUB, and an optical layer LR and an optical capping layer LCP may be disposed on the color filters CF.

In this step 220, a third color filter CF3, a second color filter CF2, and a first color filter CF1 may be disposed on the second substrate USUB. The color filters CF may be formed through various processes such as a photolithography process. The order in which the color filters CF are formed is not particularly limited.

In this step S220, the optical layer LR may be formed (e.g., deposited) to cover the color filters CF. As described above, the optical layer LR may be selectively disposed in the first sub-pixel area SPXA1.

In this step S220, the optical capping layer LCP may cover the optical layer LR to passivate the optical layer LR.

Referring to FIGS. 15, 16, and 19, in the step S240 of disposing the bank and the transparent electrode layer on the color filter, a bank BNK and a transparent electrode layer TEL may be patterned.

In this step S240, the bank BNK may be patterned, and form openings OPN. The openings OPN may be formed to respectively overlap first to third transparent electrode layers TEL1 to TEL3. The transparent electrode layer TEL may be disposed in an area in which the opening OPN is formed.

As described above, the transparent electrode layer TEL may be disposed at various positions. For example, the transparent electrode layer TEL may be patterned in case that the above-described color filter layer CFL is manufactured. For example, the optical capping layer LCP may be disposed after the transparent electrode layer TEL is disposed on the optical layer LR. In another example, in another example, the optical layer LR may be disposed after the transparent TEL is disposed on the color filters CF. In another example, in another example, the color filters CF may be disposed after the transparent electrode layer TEL is disposed on the second substrate USUB.

Referring to FIGS. 15, 16, 20, and 21, in the step S260 of disposing the color conversion layer and the light scattering layer, an inkjet printing process for manufacturing color conversion layers CCL1 and CCL2 and a light scattering layer SCT may be performed.

In this step S260, a printing apparatus PRI may discharge an ink INK, and the ink INK may have a first polarity by a polarity forming member CEL. For example, the ink INK may include a first ink INK1 for forming a first color conversion layer CCL1, a second ink INK2 for forming a second color conversion layer CCL2, and a third ink INK3 for forming the light scattering layer SCT. Each of the first to third inks INK1 to INK3 may have the first polarity.

In this step S260, an alignment guide signal may be applied to the transparent electrode layer TEL, the transparent electrode layer TEL may have a second polarity different from the first polarity. For example, each of the first to third transparent electrode layers TEL1 to TEL3 may have the second polarity. Accordingly, the first to third inks INK1 to INK3 may be moved to respectively face the first to third transparent electrode layers TEL1 to TEL3.

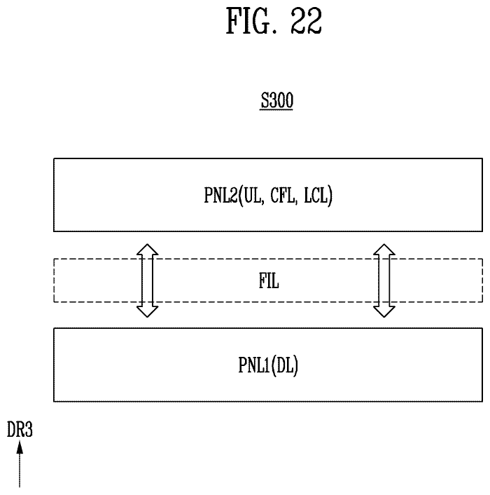

Referring to FIGS. 15 and 22, in the step S300 of bonding the first panel and the second panel together, a filling layer FIL may be interposed between the first panel PNL1 and the second panel PNL2, and the first panel PNL1 and the second panel PNL2 may be adjacent to each other with respect to the filling layer FIL interposed therebetween.

In this step S300, the first panel PNL1 including the display layer DL may be bonded to the second panel PNL2 including an upper layer UL, a color filter layer CFL, and a light controlling layer LCL.

Next, a method of manufacturing a display device DD in accordance with another embodiment of the disclosure will be described with reference to FIGS. 15 and 23 to 25. In FIGS. 23 to 25, descriptions of portions overlapping the above-described portions will be simplified or will not be repeated.

FIGS. 23 to 25 illustrate a schematic method of manufacturing a display device including features of a process of guiding movement of the ink INK using an electric field applying assembly EAA.

The method of manufacturing the display device DD in accordance with this embodiment is different from the method of manufacturing the display device in accordance with the above-described embodiment, in that the transparent electrode layer TEL is not disposed in case that the second panel PNL2 is manufactured, and the movement of the ink INK is guided using the electric field applying assembly EAA disposed on the lower surface of the second substrate SUB.

Referring to FIG. 23, the method of manufacturing the display device in accordance with this embodiment (or the step S200 of manufacturing the second panel) may not include the step S240 of disposing the bank and the transparent electrode layer on the color filter, but may include the step S220 of disposing the color filter on the second substrate, step S240′ of disposing a bank on the color filter, step S250 of disposing an electric field applying assembly on the lower surface of the second substrate, and the step S260 of disposing the color conversion layer and the light scattering layer.

Referring to FIGS. 15 and 23, the step S240′ of disposing the bank on the color filter may be performed, and the transparent electrode layer TEL may not be patterned. Accordingly, the display device DD manufactured according to the method in accordance with this embodiment may not include the transparent electrode layer TEL.

Referring to FIGS. 15, 23, and 24, the step S250 of disposing the electric field applying assembly on the lower surface of the second substrate may be performed.

In this step S250, the electric field applying assembly EAA may be disposed on the lower surface of the second substrate USUB such that an electric field for guiding the movement of the ink INK may be formed.

The electric field applying assembly EAA may include an electrode base EAB and an electric field applying electrode EAL disposed on the electrode base EAB. The electric field applying electrode EAL may include a conductive material, and play a similar role to the portions described above with reference to the transparent electrode layer TEL. For example, an alignment guide signal may be applied to the electric field applying electrode EAL, and the electric field applying electrode EAL may have a polarity. The electric field applying electrode EAL may include a first electric field applying electrode EAL1 overlapping an opening OPN corresponding to the first sub-pixel area SPXA1, a second electric field applying electrode EAL2 overlapping an opening OPN corresponding to the second sub-pixel area SPXA2, and a third electric field applying electrode EAL3 overlapping an opening OPN corresponding to the third sub-pixel area SPXA3.

Referring to FIGS. 15, 23, and 25, in the step S260 of disposing the color conversion layer and the light scattering layer, the inkjet printing process for manufacturing the color conversion layers CCL1 and CCL2 and the light scattering layer SCT may be performed.

In this step S260, the printing apparatus PRI may discharge the first to third inks INK1 to INK3 respectively to each of the openings OPN, and the first to third inks INK1 to INK3 may have the first polarity.

In this step S260, the alignment guide signal may be applied to the electric field applying electrode EAL, and the electric field applying electrode EAL may have the second polarity. For example, the first to third electric field applying electrodes EAL1 to EAL3 may have the second polarity. Accordingly, the first to third inks INK1 to INK3 may be moved to respectively face the first to third transparent electrode layers TEL1 to TEL3, and the first and second color conversion layers CCL1 and CCL2 and the light scattering layer SCT may be disposed.

Accordingly, the first and second panels PNL1 and PNL2 may be manufactured and then bonded to each other, thereby providing the display device DD in accordance with this embodiment.

There can be provided a display device having excellent display quality such as high resolution and a method of manufacturing a display device having excellent display quality such as high resolution.

There can be provided a display device, a method of manufacturing a display device, and an electronic device comprising a display device, in which process efficiency can be improved.

A display device according to an embodiment is applicable to various types of electronic devices. In an embodiment, an electronic device includes the above-described display device and may further include other modules or devices having additional functions in addition to the display device.

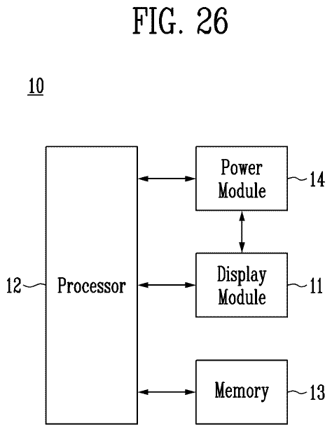

FIG. 26 is a schematic block diagram of an electronic device according to an embodiment. Referring to FIG. 26, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

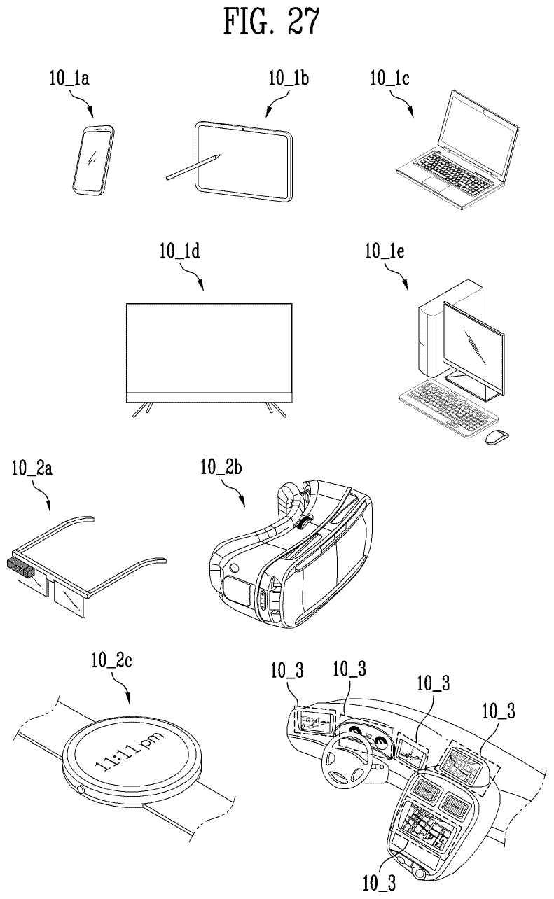

FIG. 27 shows schematic views of various embodiments of an electronic device.

Referring to FIG. 27, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a display layer disposed on a base layer, the display layer including a light emitting element;
a light controlling member disposed on the display layer, the light controlling member including a light controlling layer including a color conversion layer including a quantum dot and a light scattering layer; and
a transparent electrode layer disposed on the light controlling member such that the light emitting element and the light controlling member overlap each other in a plan view on which the base layer is disposed.

2. The display device of claim 1, further comprising:
a bank disposed on the display layer, the bank including an opening,
wherein the light controlling member is disposed in the opening.

3. The display device of claim 2, wherein the transparent electrode layer overlaps a central portion of the opening in a plan view.

4. The display device of claim 2, further comprising:
sub-pixel areas including a first sub-pixel area in which light of a first color is provided, a second sub-pixel area in which light of a second color is provided, and a third sub-pixel area in which light of a third color is provided,
wherein the sub-pixel areas and the bank do not overlap each other in a plan view, and
the transparent electrode layer includes a first transparent electrode layer disposed in the first sub-pixel area, a second transparent electrode layer disposed in the second sub-pixel area, and a third transparent electrode layer disposed in the third sub-pixel area.

5. The display device of claim 4, wherein the transparent electrode layer has a size smaller than a size of each of the sub-pixel areas.

6. The display device of claim 4, further comprising:
a base transparent electrode layer integrated with the first transparent electrode layer, the second transparent electrode layer, and the third transparent electrode layer,
wherein the base transparent electrode layer extends in a direction in which the first transparent electrode layer, the second transparent electrode layer, and the third transparent electrode layer are spaced apart from each other.

7. The display device of claim 6, further comprising:
pixels, each of the pixels including a corresponding sub-pixel area, the pixels being adjacent to each other; and
a connection transparent electrode layer integrated with the first transparent electrode layer, the second transparent electrode layer, and the third transparent electrode layer,
wherein the connection transparent electrode layer electrically connects the first to third transparent electrode layers of each of the pixels to each other.

8. The display device of claim 7, wherein a width of the transparent electrode layer is greater than a width of the connection transparent electrode layer.

9. The display device of claim 7, wherein a width of the transparent electrode layer and a width of the connection transparent electrode layer are substantially equal to each other.

10. The display device of claim 1, further comprising:
a color filter disposed on the light controlling member,
wherein the transparent electrode layer is disposed between the light controlling member and the color filter in a thickness direction.

11. The display device of claim 1, further comprising:
a color filter disposed on the light controlling member; and
an upper substrate disposed on the color filter,
wherein the transparent electrode layer is disposed between the color filter and the upper substrate in a thickness direction.

12. The display device of claim 1, further comprising:
sub-pixel areas including a first sub-pixel area in which light of a first color is provided, a second sub-pixel area in which light of a second color is provided, and a third sub-pixel area in which light of a third color is provided,
wherein the light emitting element includes a first light emitting element disposed in the first sub-pixel area, a second light emitting element disposed in the second sub-pixel area, and a third light emitting element disposed in the third sub-pixel area,
each of the first light emitting element, the second light emitting element, and the third light emitting element emits the light of the third color, and
the light controlling member includes a first color conversion layer disposed in the first sub-pixel area, a second color conversion layer disposed in the second sub-pixel area, and a light scattering layer disposed in the third sub-pixel area.

13. A method of manufacturing a display device, the method comprising:
manufacturing a first panel including a display layer including a first substrate and a light emitting element disposed on the first substrate;
manufacturing a second panel including a second substrate and a light controlling member disposed on the second substrate; and
bonding the first panel and the second panel together,
wherein the manufacturing of the second panel includes:
disposing a bank and a transparent electrode layer on the second substrate; and
providing an ink for forming the light controlling member in an opening formed by the bank, and
the providing of the ink includes supplying an alignment guide signal for the ink to the transparent electrode layer.

14. The method of claim 13, wherein the providing of the ink includes forming a first polarity in the ink.

15. The method of claim 14, wherein, in the providing of the ink, the ink has the first polarity based on a triboelectric effect.

16. The method of claim 14, wherein, in the providing of the ink, the ink has the first polarity by a polarity forming member generating an electric field.

17. The method of claim 14, wherein the providing of the ink includes:
forming a second polarity different from the first polarity in the transparent electrode layer; and
guiding, by the transparent electrode layer, movement of the ink to the opening.

18. The method of claim 13, wherein
the transparent electrode layer overlaps the opening in a plan view,
the light emitting element overlaps the transparent electrode layer and the light controlling member in a plan view, and
the light controlling member includes a color conversion layer including a quantum dot and a light scattering layer including a light scatterer.

19. An electronic device comprising
a processor configured to transfer an input control signal;
a display device configured to output an image information; and
a power module configured to supply a power to the display device,
wherein the display device comprises:
a display layer disposed on a base layer, the display layer including a light emitting element;
a light controlling member disposed on the display layer, the light controlling member including a light controlling layer including a color conversion layer including a quantum dot and a light scattering layer; and
a transparent electrode layer disposed on the light controlling member such that the light emitting element and the light controlling member overlap each other in a plan view on which the base layer is disposed.
